(19) United States
(12) Patent Application Publication
(10) Pub. No.: US 2015/0207496 A1
(43) Pub. Date: Jul. 23, 2015

(54) LATCH CIRCUIT WITH DUAL-ENDED WRITE

(71) Applicant: Apple Inc., Cupertino, CA (US)

(72) Inventor: Michael R Seningen, Austin, TX (US)

(73) Assignee: Apple Inc., Cupertino, CA (US)

(21) Appl. No.: 14/160,707

(22) Filed: Jan. 22, 2014

(51) Int. Cl. H03K 3/356

(52) U.S. Cl. CPC H03K 3/356104

(57) ABSTRACT

Embodiments of a latch circuit are disclosed that may allow a reduction in storage time of data into the latch circuit. The latch circuit may include an input circuit, a first switch, a second switch, an input circuit, and an inverting amplifier. An input of the inverting amplifier may be coupled to a storage node, and an output of the inverting amplifier may be coupled to a feedback node. The input circuit may be configured to generate buffered and complement data dependent upon received data, and the switched may be configured to allow the generated buffered data to be transferred to the feedback node, and the complement data to be transferred to the storage node.

### BACKGROUND

1. Technical Field

This invention relates to integrated circuits, and more particularly, to techniques for implement storage elements within integrated circuits.

2. Description of the Related Art

Processors, and other types of integrated circuits, typically include a number of logic circuits composed of interconnected transistors fabricated on a semiconductor substrate. Such logic circuits may be constructed according to a number of different circuit design styles. For example, combinatorial logic may be implemented via a collection of un-clocked static complementary metal-oxide semiconductor (CMOS) gates situated between clocked state elements such as flip-flops or latches. Alternatively, depending on design requirements, some combinatorial logic functions may be implemented using clocked dynamic logic, such as domino logic gates.

Flip-flops or latches typically employed for general-purpose data storage and their ability to store data make sequential and state logic design possible. For example, latches and flip-flops may be used to implement counters or other state machines. Additionally, latches and flip-flops may be used in a datapath design such as, e.g., an adder or multipler, or in the implementation of a memory-type structure such as a register or register file, for example.

Latches may be sensitive to the level of a clock signal, while flip-flops may response to the edge of the clock signal. Flip-flops may be designed in accordance with various design styles such as, e.g., D-type, set-reset, JK, or toggle, for example. Different styles of flip-flops with different characteristics, such as, e.g., data setup time and clock-to-output time, may be employed in a digital logic design in other to meet design goals.

### SUMMARY OF THE EMBODIMENTS

Various embodiments of a latch circuit are disclosed. Broadly speaking, a circuit and a method are contemplated in which the latch includes a pulse generator, an inverting amplifier, an input circuit, and first and second switches. The pulse generator may be configured to generate a pulse signal dependent upon a received clock signal. An input of the inverting amplifier may be coupled to a storage node, and an output of the inverting amplifier may be coupled to a feedback node. The input circuit may be configured to generate buffered data and complement data dependent upon received data. In response to the assertion of the pulse signal, the first switch may be configured to allow the transfer of the complement data to the storage node, and the second switch may be configured to allow the transfer of the buffered data to the feedback node.

In one embodiment, the first switch includes a Complementary Metal-Oxide Semiconductor (CMOS) transmission gate. The second switch, in a further embodiment, includes a CMOS transmission gate.

In a further embodiment, an output driver is coupled to the storage node. The output driver may be configured to generate an output signal dependent upon a voltage level of the storage node.

### BRIEF DESCRIPTION OF THE DRAWINGS

The following detailed description makes reference to the accompanying drawings, which are now briefly described.

FIG. 1 illustrates an embodiment of an integrated circuit.

FIG. 2 illustrates an embodiment of a processor that may include one or more pulse latches.

FIG. 3 illustrates an embodiment of a logic path that may include one or more pulse latches.

FIG. 4 illustrates an embodiment of a pulse latch.

FIG. 5 illustrates an embodiment of a controllable inverter.

FIG. 6 illustrates an embodiment of a pulse generation circuit.

FIG. 7 illustrates a possible distribution of pulse width values.

FIG. 8 illustrates possible waveforms for the operation of a pulse latch.

FIG. 9 depicts a flowchart illustrating an example method for operating a pulse latch.

While the disclosure is susceptible to various modifications and alternative forms, specific embodiments thereof are shown by way of example in the drawings and will herein be described in detail. It should be understood, however, that the drawings and detailed description thereto are not intended to limit the disclosure to the particular form illustrated, but on the contrary, the intention is to cover all modifications, equivalents and alternatives falling within the spirit and scope of the present disclosure as defined by the appended claims. The headings used herein are for organizational purposes only and are not meant to be used to limit the scope of the description. As used throughout this application, the word “may” is used in a permissive sense (i.e., meaning having the potential to), rather than the mandatory sense (i.e., meaning must). Similarly, the words “include,” “including,” and “includes” mean including, but not limited to.

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits. Similarly, various units/circuits/components may be described as performing a task or tasks, for convenience in the description. Such descriptions should be interpreted as including the phrase “configured to.” Reciting a unit/circuit/component that is configured to perform one or more tasks is expressly intended not to invoke 35 U.S.C. §112, paragraph six interpretation for that unit/circuit/component. More generally, the recitation of any element is expressly intended not to invoke 35 U.S.C. §112, paragraph six interpretation for that element unless the language “means for” or “step for” is specifically recited.

### DETAILED DESCRIPTION OF EMBODIMENTS

An integrated circuit may include one or more functional blocks, such as, e.g., a microcontroller or a processor, which may employ latches or flip-flops to store data or state information. Overall performance of a processor may depend on the particular implementation of flip-flop employed in the design. In some processor implementations, pulsed latches may be employed to improve certain performance parameters, such as, e.g., data timing relative to a clock edge. Such designs, however, may require the addition of extra margin in the circuit design to compensate for across chip variation in various operating parameters, such as, e.g., pulse width of pulse latch instances. The embodiments illustrated in the drawings and described below may provide techniques for reducing the time required to store data in a pulse latch, thereby improving the range of pulse widths the pulse latch may operate.

### System-on-a-Chip Overview

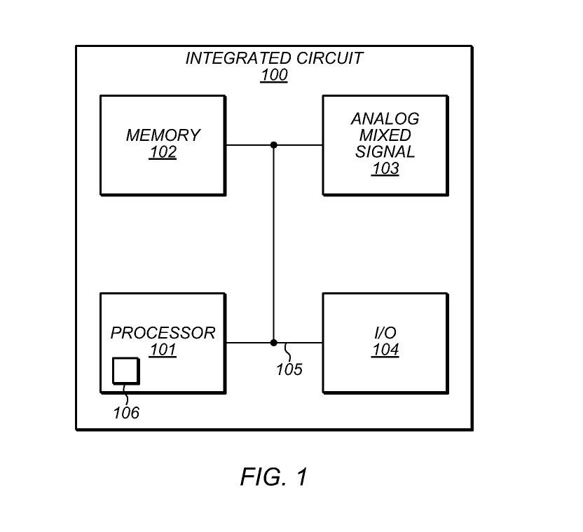

A block diagram of an integrated circuit is illustrated in FIG. 1. In the illustrated embodiment, the integrated circuit 100 includes a processor 101 coupled to memory block 102, and analog/mixed-signal block 103, and I/O block 104 through internal bus 105. In various embodiments, integrated circuit 100 may be configured for use in a desktop computer, server, or in a mobile computing application such as, e.g., a tablet or laptop computer.

As described below in more detail, processor 101 may, in various embodiments, be representative of a general-purpose processor that performs computational operations. For example, processor 101 may be a central processing unit (CPU) such as a microprocessor, a microcontroller, an application-specific integrated circuit (ASIC), or a field-programmable gate array (FPGA). In some embodiments, processing device 101 may include one or latches 106, which may be configured to assist in the performance of various functions within processor 101 such as, pipelining, for example.

Memory block 102 may include any suitable type of memory such as a Dynamic Random Access Memory (DRAM), a Static Random Access Memory (SRAM), a Read-only Memory (ROM), Electrically Erasable Programmable Read-only Memory (EEPROM), or a non-volatile memory, for example. It is noted that in the embodiment of an integrated circuit illustrated in FIG. 1, a single memory block is depicted. In other embodiments, any suitable number of memory blocks may be employed.

Analog/mixed-signal block 103 may include a variety of circuits including, for example, a crystal oscillator, a phase-locked loop (PLL), an analog-to-digital converter (ADC), and a digital-to-analog converter (DAC) (all not shown). In other embodiments, analog/mixed-signal block 103 may be configured to perform power management tasks with the inclusion of on-chip power supplies and voltage regulators. Analog/mixed-signal block 103 may also include, in some embodiments, radio frequency (RF) circuits that may be configured for operation with wireless networks.

I/O block 104 may be configured to coordinate data transfer between integrated circuit 100 and one or more peripheral devices. Such peripheral devices may include, without limitation, storage devices (e.g., magnetic or optical media-based storage devices including hard drives, tape drives, CD drives, DVD drives, etc.), audio processing subsystems, or any other suitable type of peripheral devices. In some embodiments, I/O block 104 may be configured to implement a version of Universal Serial Bus (USB) protocol or IEEE 1394 (Firewire®) protocol.

I/O block 104 may also be configured to coordinate data transfer between integrated circuit 100 and one or more devices (e.g., other computer systems or integrated circuits) coupled to integrated circuit 100 via a network. In one embodiment, I/O block 104 may be configured to perform the data processing necessary to implement an Ethernet (IEEE 802.3) networking standard such as Gigabit Ethernet or 10-Gigabit Ethernet, for example, although it is contemplated that any suitable networking standard may be implemented. In some embodiments, I/O block 104 may be configured to implement multiple discrete network interface ports.

### Processor Overview

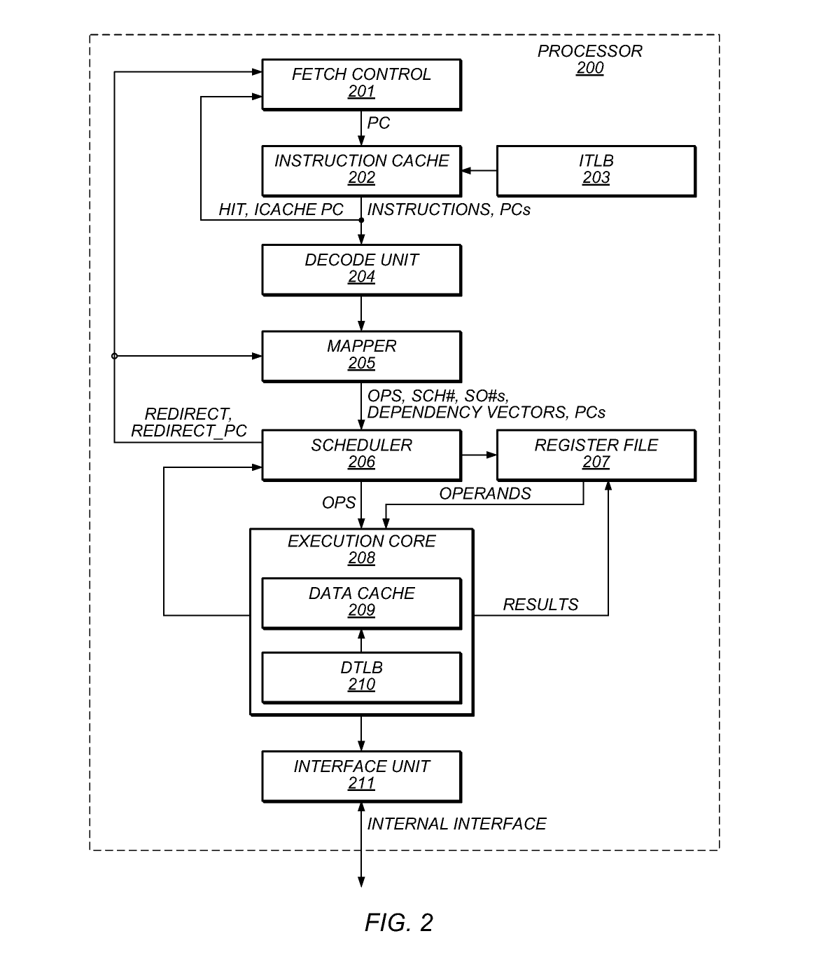

Turning now to FIG. 2, a block diagram of an embodiment of a processor 200 is shown. Processor 200 may, in some embodiments, corresponds to processor 101 of SoC 100 as illustrated in FIG. 1. In the illustrated embodiment, the processor 200 includes a fetch control unit 201, an instruction cache 202, a decode unit 204, a mapper 209, a scheduler 206, a register file 207, an execution core 208, and an interface unit 211. The fetch control unit 201 is coupled to provide a program counter address (PC) for fetching from the instruction cache 202. The instruction cache 202 is coupled to provide instructions (with PCs) to the decode unit 204, which is coupled to provide decoded instruction operations (ops, again with PCs) to the mapper 205. The instruction cache 202 is further configured to provide a hit indication and an ICache PC to the fetch control unit 201. The mapper 205 is coupled to provide ops, a scheduler number (SCH#), source operand numbers (SO#s), one or more dependency vectors, and PCs to the scheduler 206. The scheduler 206 is coupled to receive replay, mispredict, and exception indications from the execution core 208, is coupled to provide a redirect indication and redirect PC to the fetch control unit 201 and the mapper 205, is coupled to the register file 207, and is coupled to provide ops for execution to the execution core 208. The register file is coupled to provide operands to the execution core 208, and is coupled to receive results to be written to the register file 207 from the execution core 208. The execution core 208 is coupled to the interface unit 211, which is further coupled to an external interface of the processor 200.

Fetch control unit 201 may be configured to generate fetch PCs for instruction cache 202. In some embodiments, fetch control unit 201 may include one or more types of branch predictors 212. For example, fetch control unit 202 may include indirect branch target predictors configured to predict the target address for indirect branch instructions, conditional branch predictors configured to predict the outcome of conditional branches, and/or any other suitable type of branch predictor. During operation, fetch control unit 201 may generate a fetch PC based on the output of a selected branch predictor. If the prediction later turns out to be incorrect, fetch control unit 201 may be redirected to fetch from a different address. When generating a fetch PC, in the absence of a nonsequential branch target (i.e., a branch or other redirection to a nonsequential address, whether speculative or non-speculative), fetch control unit 201 may generate a fetch PC as a sequential function of a current PC value. For example, depending on how many bytes are fetched from instruction cache 202 at a given time, fetch control unit 201 may generate a sequential fetch PC by adding a known offset to a current PC value.

The instruction cache 202 may be a cache memory for storing instructions to be executed by the processor 200. The instruction cache 202 may have any capacity and construction (e.g. direct mapped, set associative, fully associative, etc.). The instruction cache 202 may have any cache line size. For example, 64 byte cache lines may be implemented in an embodiment. Other embodiments may use larger or smaller cache line sizes. In response to a given PC from the fetch control unit 201, the instruction cache 202 may output up to a maximum number of instructions. It is contemplated that processor 200 may implement any suitable instruction set architecture (ISA), such as, e.g., the ARM™, PowerPC™, or x86 ISAs, or combinations thereof.

In some embodiments, processor 200 may implement an address translation scheme in which one or more virtual address spaces are made visible to executing software. Memory accesses within the virtual address space are translated to a physical address space corresponding to the actual physical memory available to the system, for example using a set of page tables, segments, or other virtual memory translation schemes. In embodiments that employ address translation, the instruction cache 14 may be partially or completely addressed using physical address bits rather than virtual address bits. For example, instruction cache 202 may use virtual address bits for cache indexing and physical address bits for cache tags.

In order to avoid the cost of performing a full memory translation when performing a cache access, processor 200 may store a set of recent and/or frequently-used virtual-to-physical address translations in a translation lookaside buffer (TLB), such as Instruction TLB (ITLB) 203. During operation, ITLB 203 (which may be implemented as a cache, as a content addressable memory (CAM), or using any other suitable circuit structure) may receive virtual address information and determine whether a valid translation is present. If so, ITLB 203 may provide the corresponding physical address bits to instruction cache 202. If not, ITLB 203 may cause the translation to be determined, for example by raising a virtual memory exception.

The decode unit 204 may generally be configured to decode the instructions into instruction operations (ops). Generally, an instruction operation may be an operation that the hardware included in the execution core 208 is capable of executing. Each instruction may translate to one or more instruction operations which, when executed, result in the operation(s) defined for that instruction being performed according to the instruction set architecture implemented by the processor 200. In some embodiments, each instruction may decode into a single instruction operation. The decode unit 16 may be configured to identify the type of instruction, source operands, etc., and the decoded instruction operation may include the instruction along with some of the decode information. In other embodiments in which each instruction translates to a single op, each op may simply be the corresponding instruction or a portion thereof (e.g. the opcode field or fields of the instruction). In some embodiments in which there is a one-to-one correspondence between instructions and ops, the decode unit 204 and mapper 205 may be combined and/or the decode and mapping operations may occur in one clock cycle. In other embodiments, some instructions may decode into multiple instruction operations. In some embodiments, the decode unit 16 may include any combination of circuitry and/or microcoding in order to generate ops for instructions. For example, relatively simple op generations (e.g. one or two ops per instruction) may be handled in hardware while more extensive op generations (e.g. more than three ops for an instruction) may be handled in microcode.

Ops generated by the decode unit 204 may be provided to the mapper 205. The mapper 205 may implement register renaming to map source register addresses from the ops to the source operand numbers (SO#s) identifying the renamed source registers. Additionally, the mapper 205 may be configured to assign a scheduler entry to store each op, identified by the SCH#. In an embodiment, the SCH# may also be configured to identify the rename register assigned to the destination of the op. In other embodiments, the mapper 205 may be configured to assign a separate destination register number. Additionally, the mapper 205 may be configured to generate dependency vectors for the op. The dependency vectors may identify the ops on which a given op is dependent. In an embodiment, dependencies are indicated by the SCH# of the corresponding ops, and the dependency vector bit positions may correspond to SCH#s. In other embodiments, dependencies may be recorded based on register numbers and the dependency vector bit positions may correspond to the register numbers.

The mapper 205 may provide the ops, along with SCH#, SO#s, PCs, and dependency vectors for each op to the scheduler 206. The scheduler 206 may be configured to store the ops in the scheduler entries identified by the respective SCH#s, along with the SO#s and PCs. The scheduler may be configured to store the dependency vectors in dependency arrays that evaluate which ops are eligible for scheduling. The scheduler 206 may be configured to schedule the ops for execution in the execution core 208. When an op is scheduled, the scheduler 206 may be configured to read its source operands from the register file 207 and the source operands may be provided to the execution core 208. The execution core 208 may be configured to return the results of ops that update registers to the register file 207. In some cases, the execution core 208 may forward a result that is to be written to the register file 207 in place of the value read from the register file 207 (e.g. in the case of back to back scheduling of dependent ops).

The execution core 208 may also be configured to detect various events during execution of ops that may be reported to the scheduler. Branch ops may be mispredicted, and some load/store ops may be replayed (e.g. for address-based conflicts of data being written/read). Various exceptions may be detected (e.g. protection exceptions for memory accesses or for privileged instructions being executed in non-privileged mode, exceptions for no address translation, etc.). The exceptions may cause a corresponding exception handling routine to be executed.

The execution core 208 may be configured to execute predicted branch ops, and may receive the predicted target address that was originally provided to the fetch control unit 201. The execution core 208 may be configured to calculate the target address from the operands of the branch op, and to compare the calculated target address to the predicted target address to detect correct prediction or misprediction. The execution core 208 may also evaluate any other prediction made with respect to the branch op, such as a prediction of the branch op's direction. If a misprediction is detected, execution core 208 may signal that fetch control unit 201 should be redirected to the correct fetch target. Other units, such as the scheduler 206, the mapper 205, and the decode unit 204 may flush pending ops/instructions from the speculative instruction stream that are subsequent to or dependent upon the mispredicted branch.

The execution core may include a data cache 209, which may be a cache memory for storing data to be processed by the processor 200. Like the instruction cache 202, the data cache 209 may have any suitable capacity, construction, or line size (e.g. direct mapped, set associative, fully associative, etc.). Moreover, the data cache 209 may differ from the instruction cache 202 in any of these details. As with instruction cache 202, in some embodiments, data cache 26 may be partially or entirely addressed using physical address bits. Correspondingly, a data TLB (DTLB) 210 may be provided to cache virtual-to-physical address translations for use in accessing the data cache 209 in a manner similar to that described above with respect to ITLB 203. It is noted that although ITLB 203 and DTLB 210 may perform similar functions, in various embodiments they may be implemented differently. For example, they may store different numbers of translations and/or different translation information.

The register file 207 may generally include any set of registers usable to store operands and results of ops executed in the processor 200. In some embodiments, the register file 207 may include a set of physical registers and the mapper 205 may be configured to map the logical registers to the physical registers. The logical registers may include both architected registers specified by the instruction set architecture implemented by the processor 200 and temporary registers that may be used as destinations of ops for temporary results (and sources of subsequent ops as well). In other embodiments, the register file 207 may include an architected register set containing the committed state of the logical registers and a speculative register set containing speculative register state.

The interface unit 211 may generally include the circuitry for interfacing the processor 200 to other devices on the external interface. The external interface may include any type of interconnect (e.g. bus, packet, etc.). The external interface may be an on-chip interconnect, if the processor 200 is integrated with one or more other components (e.g. a system on a chip configuration). The external interface may be on off-chip interconnect to external circuitry, if the processor 200 is not integrated with other components. In various embodiments, the processor 200 may implement any instruction set architecture.

It is noted that the embodiment of a processing device illustrated in FIG. 2 is merely an example. In other embodiments, different functional block or configurations of functional blocks are possible and contemplated.

### Logic Paths and Latch Design

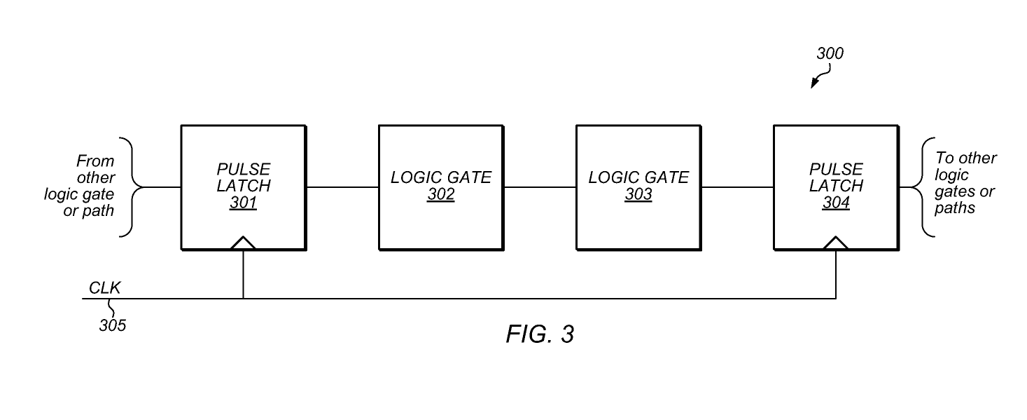

In some designs, it may be advantageous to use one or more pulse latches within a logic path instead of a flip-flop circuit. An example of a portion of a logic path is illustrated in FIG. 3. In the illustrated embodiment, pulse latch 301 is coupled to logic gate 302, which is in turn, coupled to logic gate 303. Logic gate 303 is coupled to another pulse latch 304. The illustrated embodiment also includes a clock input 305 denoted as “CLK.” Generally speaking, pulse latches 301 and 304 may correspond to any suitable state element, such as a static or dynamic flip-flop. Pulse latches 301 and 304 may operate to capture and store input data in response to clock input 305.

Logic gates 302 and 303 may be configured to implement combinatorial logic functions of any suitable type (e.g., AND, OR, NAND, NOR, XOR, and XNOR, or any suitable Boolean expression). Either of logic gates 302 or 303 may be implemented using static or dynamic logic. For example, if implemented using dynamic logic, logic gates 302 and 303 may also be clocked by clock input 305, or they may be clocked by a clock signal (not shown) that is derived from clock input 305. It is noted that the number of logic gates and connectivity shown in FIG. 3 are merely an illustrative example, and that in other embodiments, other numbers and configurations of gates and state elements may be employed.

During operation, the output of pulse latch 301 propagates to logic gate 302, where it is processed in accordance with the logical function implemented in logic gate 302. Although only one input is shown to logic gate 302, in various embodiments, logic gate 302 may include multiple inputs from different logic paths. The output of logic gate 302 may then propagate to logic gate 303 where it is further processed in accordance with the logic function implemented in logic gate 303. As previously described above in regards to logic gate 302, logic gate 303 may, in other embodiments, include multiple inputs. The output of logic gate 302 may then propagate to the input of pulse latch 304.

When clock input 305 is asserted, pulse latch 304 may then capture the data output by logic gate 303. In response to the assertion of clock input 305, pulse latch 304 may generate an internal pulse, allowing data output by logic gate 303 to propagate into pulse latch 304. While pulse latch 304 is in transparent mode, any change in the data output by logic gate 303 may ripple through pulse latch 304. Provided the desired data is valid before the internal pulse of pulse latch 304 ends, pulse latch 304 can capture the desired data.

In addition to ensure the capture of the desired data, the output of logic gate 303 must also be maintained until the pulse latch 304 transitions back to opaque mode in which no further changes in the input data are accepted. The amount of time the data must be maintained at the input of a latch is commonly referred to as the “hold time” of the latch.

When clock input 305 is asserted and pulse latch 304 captures the output of logic gate 303, pulse latch 301 accepts new data from a logic gate or different data path (both not shown). The newly captured data begins to propagate through pulse latch 301 towards logic gate 302. The new may continue to propagate through logic gates 302 and 303 provided that any change on the output of logic gate 303 occurs after the hold time of latch 304. In various embodiments, the number of gates between pulse latches 301 and 304 may be adjusted to prevent any violation of the aforementioned hold time requirements associated with pulse latch 304.

The logic path illustrated in FIG. 3 may correspond to any of numerous different types of digital logic circuits, and may generally include any series of gates bounded by state elements. For example, the logic path may correspond to a portion of a datapath within a processing device, such as processing device 200 as described above with respect to FIG. 2. The datapath may be a portion of an adder, shifter, multiplier, divider, buffer, register file, other any other type of circuit or functional unit that operates to store or operate on data during the course of instruction execution. The logic path may also correspond to control paths within a processor that generate signals that control the operation of datapath or other elements within the processor. It is noted, however, that other configurations of logic paths are possible and contemplated.

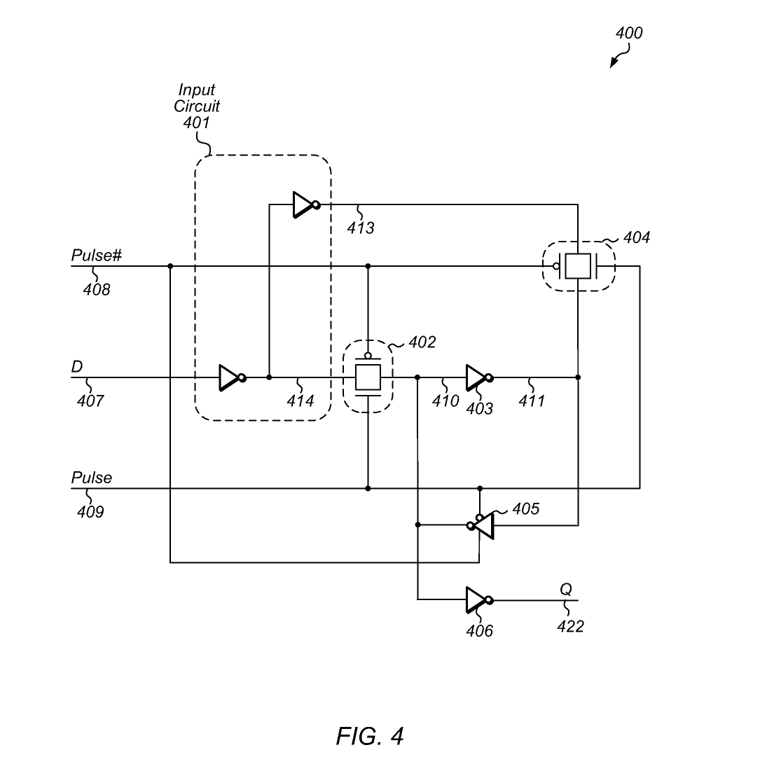

Turning to FIG. 4, a pulse latch is illustrated according to one of several possible embodiments. In some embodiments, pulse latch 400 may correspond to latch 106 embedded within processor 101. The illustrated embodiment includes pulse input 409 denoted as “pulse,” complement pulse input 408 denoted as “pulse#,” data input 407 denoted as “D,” and data output 412 denoted as “Q.”

In the illustrated embodiment, data input 407 is coupled to input circuit 401 which may be configured to generate complement data 414 and buffered data 413. In some embodiments, input circuit 401 may include one or more inverting amplifiers coupled in series while, in other embodiments, input circuit 401 may include a combination of inverting and non-inverting amplifiers.

Buffered data 413 is input to switch 404, and complement data 414 is input to switch 402. Switch 402 is coupled to the input of inverter 403 via storage node 410, and switch 404 is coupled to the output of inverter 403 via feedback node 411. Switches 402 and 404 are controlled by pulse input 409 and complement pulse input 408. In various embodiments, switches 402 and 404 may be particular embodiments of a “pass” or “transmission” gate, and may each include a n-channel metal-oxide-semiconductor field-effect transistor (MOSFET), and a p-channel MOSFET. It is noted that, in various embodiments, a “transistor” may correspond to one or more transconductance elements such as a junction field-effect transistor (JFET), for example.

The input of inverter 405 is coupled to feedback node 411, and the output of inverter 405 is coupled to storage node 410. The input of inverter 406 is coupled to storage node 410, and the output of inverter 406 is coupled to data output 412. It is noted that static complementary metal-oxide-semiconductor (CMOS) inverters, such as those shown and described herein, may be a particular embodiment of an inverting amplifier that may be employed in the circuits described herein. However, in other embodiments, any suitable configuration of inverting amplifier that is capable of inverting the logical sense of a signal may be used, including inverting amplifiers built using technology other than CMOS.

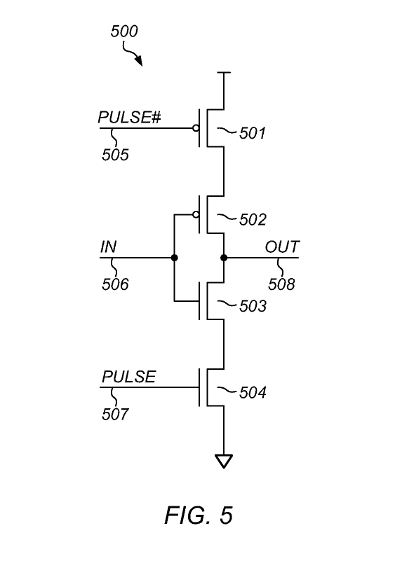

An inverter such as, inverter 405, for example, having one or more control inputs may also be referred to as a herein as a “clocked inverter” or a “controllable inverter,” although it is noted that the signals that drive the control inputs need not be pulse signals, but may be any sort of control signal. In the illustrated embodiment, one control input of inverter 405 is coupled to pulse 409, and another control input of inverter 405 is coupled to complement pulse 408. The operation of a clocked inverter will be described in more detail below in reference to FIG. 5.

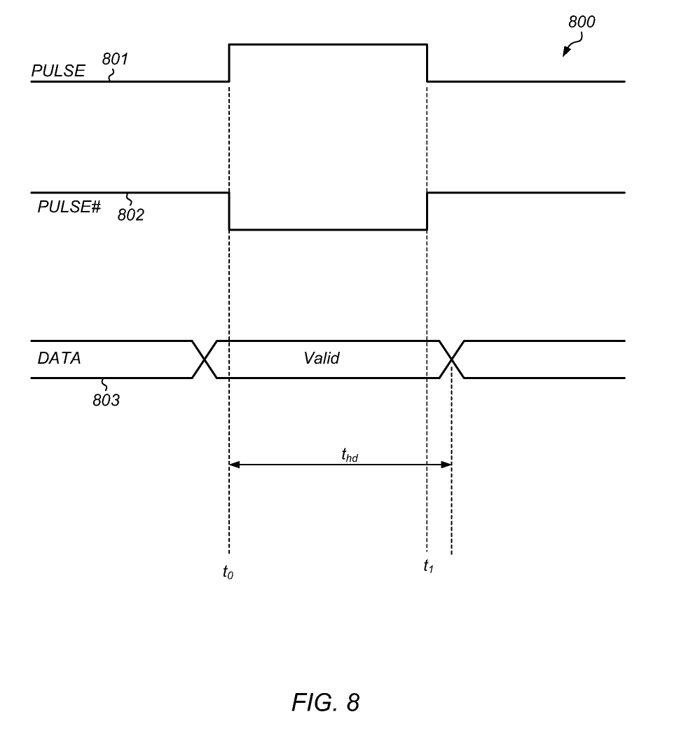

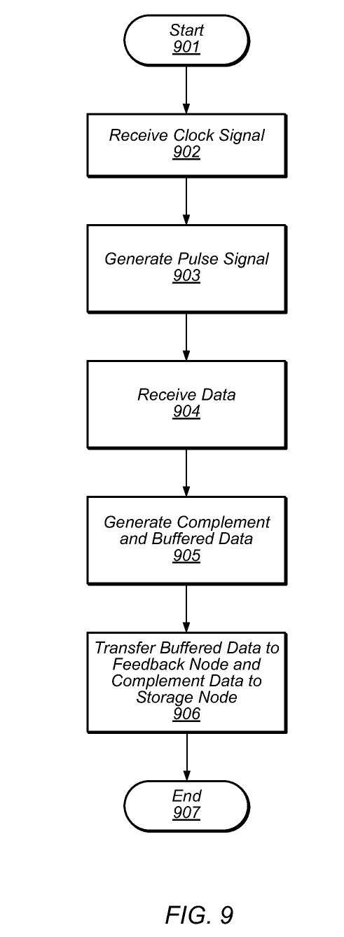

During operation, as will be described in more detail in reference to FIG. 8 and FIG. 9, the logic level on data input 407 may inverted by input circuit 401 to create complement data 414, and may be buffered to created buffered data 413. Initially, pulse 409 may be at a logic low level and complement pulse 408 may be at a logic high level, thereby keeping switches 402 and 404 open, and enabling inverter 405, allowing the logic level on feedback node 411 to be inverted and feed back onto storage node 410. The feedback path through inverter 405 may allow pulse latch 400 to store data. When storing data, pulse latch 400 is commonly referred to as being in “latched mode” or “opaque mode.” While in opaque mode, pulse latch 400 may be reset or initialized to a known state through the use of reset or initialization circuitry (not shown).

It is noted that “low” or “low logic level” refers to a voltage at or near ground and that “high” or “high logic level” refers to a voltage level sufficiently large to turn on a n-channel MOSFET and turn off a p-channel MOSFET. In other embodiments, different technology may result in different voltage levels for “low” and “high.”

When pulse 409 and complement pulse 408 transition to a high logic level and a low logic level, respectively, both switches 404 and 402 close. As the two switches close, buffered data 413 is allowed to transfer to feedback node 411, and complement data is allowed to transfer to storage node 410. Inverter 405 may, in various embodiments, be disabled in response to the aforementioned change in the logic state of the pulse 409 and complement pulse 408. As complement data 414 is transferred to storage node 410, inverter 406 generates data output 422 in response to any change on storage node 410. While pulse 409 is at a logic low level and complement pulse 409 is at a logical high level, pulse latch 400 is commonly referred to as being “transparent.” By transferring data to both the input and output of inverter 403, the time required to store new data may, in various embodiments, be reduced. Such a reduction in storage time may allow for a reduced pulse width or may provide additional margin to accommodate variation the width of pulse 409 or complement pulse 408.

As pulse 409 returns to a low logic level and complement pulse 408 returns to a high logic level, switches 402 and 404 open, isolating input circuit 401 from storage node 410 and feedback node 411. Inverter 405 may then also reactivate providing the necessary feedback to maintain the newly stored data.

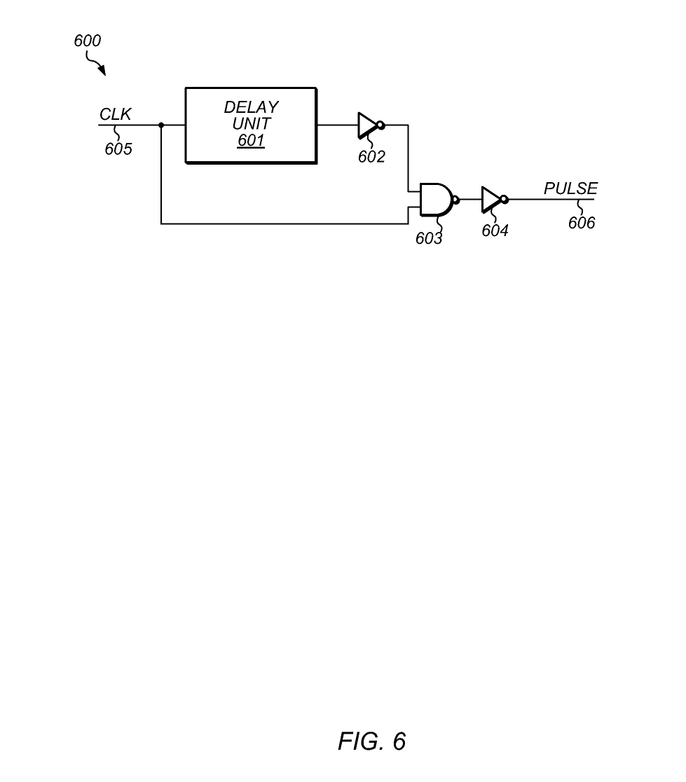

It is noted that, in the illustrated embodiment, pulse latch 400 has pulse and complement pulse inputs. In other embodiments, a pulse generator, such as will be described below in reference to FIG. 6, may be included in a pulse latch. In such cases, a clock signal may be included as an input to the pulse latch.

Although pulse latch 400 may be used within logic paths as illustrated in FIG. 3, they may also be used in any suitable storage application. For example, one or more of pulse latch 400 may be arranged to implement a memory-type structure, such as a register, a register file, a first-in-first-out (FIFO) queue, a last-in-last-out (LIFO) queue, a cache or any suitable arrangement.

An embodiment of a controllable inverter is illustrated in FIG. 5. The illustrated embodiment includes a pulse input 507 denoted as “pulse,” a complement pulse input 505 denoted as “pulse#,” a data input 506 denoted as “in,” and a data output 508 denoted as “out.” In some embodiments, pulse input 507 may correspond to pulse signal 409 of pulse latch 400, and complement pulse input 505 may correspond to complement pulse signal 408 of pulse latch 400.

In the illustrated embodiment, data input 506 controls pull-up device 502 and pull-down device 503, which are each coupled to data output 508. Pull-up device 502 is further coupled to pull-up device 501, which is controlled by complement pulse input 505, forming a pull-up path. Pull-down device 503 is further coupled to pull-down device 504, which is controlled by pulse input 507, forming a pull-down path. In various embodiments, pull-up devices 501 and 502 may include p-channel MOSFETs, and pull-down device 503 and 504 may include n-channel MOSFETs. The source connection of p-channel MOSFETs employed as pull-up devices may, in some embodiments, be coupled to a power supply, and the source of n-channel MOSFETs employed as pull-down devices may, in some embodiments, be coupled to ground or a circuit node at or near ground potential.

It is noted that in various embodiments, a pull-up path (also referred to herein as a pull-up network) may include one or more transistors coupled, in a series fashion, parallel fashion, or combination thereof, between a circuit node and a power supply. It is further noted that a pull-down path (also referred to herein as a pull-down network) may include one or more transistors coupled, in a series fashion, parallel fashion, or combination thereof, between a circuit node and ground or a circuit node at or near ground potential.

During operation, when pulse input 507 is high and complement pulse input 505 is low, pull-down device 504 and pull-up device 501 are both on, thereby allowing pull-up device 502 and pull-down device 503 to function as an inverting amplifier. In this mode of operation, the logical polarity of data presented on data input 506 is inverted on data output 508.

When pulse input 507 is low and complement pulse input 505 is high, pull-down device 505 and pull-up device 501 are off, thereby preventing any current to flow from the power supply or discharge into ground. In this mode of operation, controllable inverter 500 is inactive, and the impedance of data output 508 is high, which may, in some embodiments, be treated as a third logic state to implement a three state (commonly referred to as “tri-state”) logic system.

In some embodiments, pulse input 507 and complement pulse input 505 may be operated independently allowing for either the pull-up path or the pull-down path of controllable inverter 500 to be active. For example, pulse input 507 and complement pulse input 508 may both be at a low logic level, disabling pull-down device 504 and enabling pull-up device 501. Data output 508 cannot be discharge to ground since pull-down device 504 is disabled. When input data 506 is at a low logic level, data output 508 may be charged to a high logic level through pull-up devices 501 and 502. Data output 508 may be tri-state when data input 506 is at a high logic level.

It is noted that the embodiment of a controllable inverter illustrated in FIG. 5 is merely an example. In other embodiments, different devices and different configurations of devices are possible and contemplated.

Turning to FIG. 6, an embodiment of a pulse generator circuit is depicted. In the illustrated embodiment, pulse generator 600 includes clock input 605, denoted as “clk,” and pulse signal 606, denoted as “pulse.” Clock input 605 is coupled to delay unit 601 and to an input of NAND gate 603. The output of delay unit 601 is coupled to the input of inverter 602 which is, in turn, coupled to another input of NAND gate 603. The output of NAND gate 603 is coupled to inverter 604, whose output is coupled to pulse signal 606.

Delay unit 601 may, in various embodiments, be configured to delay transitions of clock signal 605. For example, a rising edge transition on clock signal 605 may occur at the output of delay unit 601 after a predetermined time period has elapsed. The amount of delay that delay unit 601 provides may, in various embodiments, be determined by circuit simulation prior to manufacture. In some embodiments, additional delay may be included in delay unit 601 to account for manufacturing variation in the transistors included in the pulse generation circuit as well as in a pulse latch, such as, pulse latch 400, for example.

In some embodiments, delay unit 601 may include a chain of inverters, i.e., two more serially coupled inverters, wherein each inverter of the chain contributes its inherent operating delay to the overall delay of the chain. The delay of each inverter may, in various embodiments, be adjusted through the use of one or more analog bias signals. The amount of current each current starved inverter may source to or sink from its output node may be varied dependent on the bias signals, thereby adjusting the propagation delay through the inverter. It is noted that although inverter chains are described in reference to delay unit 601, in various embodiments, any suitable circuit capable of delaying a signal may be employed.

During operation, a rising edge on clk 605 may be delayed by delay unit 601. The logical polarity of the delayed version of clk 605 may be inverted by inverting amplifier 602. NAND gate 603 may then logically combine the output of inverting amplifier 602 and clk 605 in accordance with the logical not-AND function, to create a low-going pulse at the output of NAND gate 603. The logical polarity of the output of NAND gate 603 may then be inverted by inverting amplifier 604 to create high-going pulse 606. The width of pulse 606 may, in some embodiments, correspond to the delay provided by delay unit 601. An additional inverting amplifier (not shown) may, in various embodiments, invert the logical polarity of pulse 606 to create a complement pulse (not shown).

It is noted that the pulse generator illustrated in FIG. 6 is merely an example. In other embodiments, different delay units, and different combinations of the clock signal and delayed clock signal may be employed.

As previously mentioned, variation in the manufacture of a semiconductor may result in variation across a single integrated circuit between two devices or transistors intended to have similar electrical characteristics. The variation may, in some embodiments, be the result of slight differences in lithography between the various devices, which introduces slight differences in the physical dimensions of the devices. In other cases, differences in dopant levels between devices may change the electrical characteristics such as, e.g., threshold voltage or transconductance.

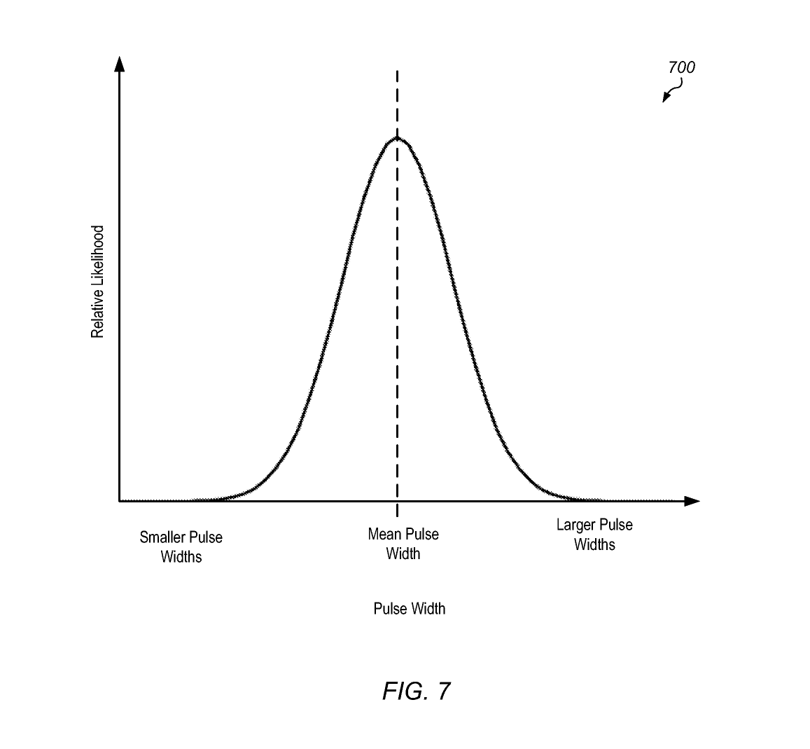

Such variation in the electrical characteristics of transistors may result in variation of operating parameters of circuits intended to have similar characteristics. For example, the hold time of one instance of pulse latch, such as pulse latch 400 as illustrated in FIG. 4, may differ from the hold time of a different instance of the pulse latch within an SoC. A distribution of different values for a given operating parameter, such as, e.g., pulse width of a pulse generator, may be possible. An example of such a distribution is illustrated in FIG. 7.

In the illustrated distribution, the relative likelihood of a given pulse width is depicted as being normally distributed (also referred to as being a “Gaussian distribution”). That is, distribution is centered on a mean value with some pulse generators creating pulses that are of shorter duration, and some pulse generators creating pulses of longer duration. In some embodiments, circuits are designed based on estimations of distributions of operating parameters made prior to manufacture of the circuits to avoid yield loss due to the manufacturing variation. To accommodate the ends or “tails” of the distribution, circuits are often designed to accommodate worst-case parameters. This practice is commonly referred to as “adding margin” to the design. Such design practices may, in various embodiments, increase the physical size of a circuit, increase the power consumption of a circuit, and the like.

In some cases, however, other circuit techniques may be applied to add needed margin into the circuit without impacting area or power. For example, as described above in regards to FIG. 4, transferring data to both the storage node and feedback node of a pulse latch may, in various embodiments, result in a shorter time necessary to store new data in the pulse latch. Such a reduction in storage time may allow circuits to operate whose pulse widths are shorter than the average pulse width, thereby improving overall yield.

It is noted that the distribution depicted in FIG. 7 is merely an example of a specific operating parameter. In other embodiments, different distributions for different operating parameters are possible, each of which may have differing characteristics.

Turning to FIG. 8, example waveforms for the operation of a pulse latch, such as, e.g., pulse latch 400, are illustrated. Referring collectively to the waveforms depicted in FIG. 8 and pulse latch 400 of FIG. 4, pulse 409 (waveform 801) is at a low logic level and complement pulse 408 (waveform 802) is at a high logic level. While the pulse signals are in this state, switches 402 and 404 are open, and inverter 405 is active, allowing data to be stored in the feedback loop formed by inverters 403 and 405.

Just prior to time t0, data input 407 (waveform 803) changes state. Input circuit 401 generates buffered data 413 and complement data 407 in response to the change in input data 407. At time t₀, pulse 409 (waveform 801) transitions to a high logic level and complement pulse 408 (waveform 802) transitions to a low logic level. In response to the change in logic levels of the pulse signals, switches 402 and 404 close, and inverter 405 deactivates, allowing the transfer of buffered data 413 to feedback node 411 and complement data 414 to storage node 410.

At time t₁, pulse 409 (waveform 801) transitions back to a low logic level, and complement pulse 408 (waveform 802) transitions back to a high logic level. The width of the pulse signals, i.e., the difference between time t₀ and t₁, may vary from one instance of pulse latch 400 to another in accordance with the distribution of pulse widths depicted in FIG. 7. In some embodiments, by transferring buffered data and complement data to the feedback and storage nodes, respectively, of a pulse latch, pulses shorter than the mean pulse width of a distribution may still be of sufficient duration to allow the pulse latch to store new data. In order to ensure the data has been stored in pulse latch 400, the valid data on data input 407 (waveform 803) extends past time t1.

It is noted that the waveforms depicted in FIG. 8 are merely an example. In other embodiments, different pulse widths, and different hold times are possible.

Turning to FIG. 9, a flowchart depicting an embodiment of a method for operating a pulse latch is illustrated. Referring collectively to the pulse latch depicted in FIG. 4, and the flowchart of FIG. 9, the method begins in block 901. A clock signal may then be received (block 902). In some embodiments, the clock signal may be a system-level clock of a SoC, such as, e.g., SoC 100 as illustrated in FIG. 1. The clock signal may, in other embodiments, be a dedicated clock employed as a timing reference for a communication bus between functional blocks within an SoC or communication link between different integrated circuits.

Using the received clock signal, a pulse signal may then be generated (block 903). In some embodiments, a pulse circuit such as, e.g., pulse circuit 600 as illustrated in FIG. 6, may be employed to generate the pulse signal. Such pulse circuits may, in various embodiments, be included as part of a pulse latch, such as, pulse latch 400 as illustrated in FIG. 4. In other embodiments, however, a pulse signal generated by a pulse generator may be used to operation multiple pulse latch circuits. A pulse generator may, in various embodiments, also generate a complement version, i.e., a pulse having the opposite logical polarity, of the pulse signal. The pulse signal and the complement pulse signal, such as, e.g., pulse 409 and pulse#408, may be used to operate components within a pulse latch. For example, in pulse latch 400, switches 402 and 402 may close, thereby coupling the output of input circuit 401 to storage node 410 and feedback node 411. Additionally, controlled inverting amplifier 405 may be disabled while pulse 409 is at a high logic level and pulse#408 is at a low logic level.

The width of the pulse may be predetermined by circuit analysis before manufacture of an integrated circuit employing the pulse latch. In some embodiment, the width of the pulse may be adjusted prior to manufacture to compensate for variation in the width of the pulse due to variation in manufacture. Such compensation is commonly referred to as “adding margin.”

Data to be stored may then be received by input circuit 401 (block 904), and buffered and complement versions of the received data may then be generated by input circuit 401 (block 905). In some embodiments, the received data may be the output of a chain of logic gates within a processor or other logic circuit. The received data may, in other embodiments, be data transmitted from one integrated circuit to another. Input circuit 401 may, in various embodiments, employ one or more inverting or non-inverting amplifiers to generate the buffered and complement versions of the received data.

Once the buffered and complement versions of the received data have been generated, the buffered and complement data may then be transferred to feedback node 411 and storage node 410 of pulse latch 400, respectively (block 906). In some embodiments, by transferring the buffered data to feedback node 411 in addition to transferring the complement data to storage node 410, a reduction in write time may be realized which may mitigate variations in the width of pulse 409 and pulse#408 resulting from variation in a semiconductor manufacturing process.

Once pulse 409 transitions to a low logic level, and pulse#408 transitions to a high logic level, switches 402 and 404 open, and controlled inverting amplifier 405 reactivates, thereby storing the received data in pulse latch 400 through the feedback loop formed by inverting amplifier 403 and controlled inverting amplifier 405. Pulse latch 400 may then be ready to receive and store new data on a subsequent clock cycle. The method may then conclude in block 907.

It is noted that in the embodiment illustrated in FIG. 9, the operations are depicted as being performed in a sequential fashion. In other embodiments, one or more of the operations may be performed in parallel or in a different order.

Numerous variations and modifications will become apparent to those skilled in the art once the above disclosure is fully appreciated. It is intended that the following claims be interpreted to embrace all such variations and modifications.

What is claimed is:

1. An apparatus, comprising:
a pulse generator unit configured to receive a clock signal and generate a pulse signal dependent upon the received clock signal;
an first inverting amplifier, wherein an input of the first inverting amplifier is coupled to a storage node, and an output of the first inverting amplifier is coupled to a feedback node;
an input circuit configured to receive data and generate complement data and buffered data dependent upon the received data;
a first switch configured to selectively transfer the complement data to the storage node responsive to an assertion of the pulse signal; and
a second switch configured to selectively transfer the buffered data to the feedback node responsive to the assertion of the pulse signal.

2. The apparatus of claim 1, wherein the first switch comprises a Complementary Metal-Oxide Semiconductor (CMOS) transmission gate, and wherein the second switch comprises a CMOS transmission gate.

3. The apparatus of claim 1, further comprising an output driver coupled to the storage node, wherein the output driver is configured to generate an output signal dependent upon a voltage level of the storage node.

4. The apparatus of claim 1, wherein the pulse generator unit includes one or more delay generator units.

5. The apparatus of claim 1, further comprising a second inverting amplifier, wherein an input of the second amplifier is coupled to the feedback node, and an output of the second amplifier is coupled to the storage node.

6. The apparatus of claim 5, wherein the second inverting amplifier is configured to deactivate responsive to the generated pulse signal.

7. The apparatus of claim 1, wherein the input circuit includes one or more inverting amplifiers.

8. A method for operating a latch circuit, the method comprising:
generating a pulse signal;
generating complement data upon received data;
transferring the generated complement data to a storage node of the latch circuit responsive to the generated pulse signal; and
transferring the received data to a feedback node of the latch circuit responsive to the generated pulse signal.

9. The method of claim 8, wherein transferring the generated complement data to the storage node comprises closing a first switch.

10. The method of claim 9, wherein transferring the received data to the feedback node comprises closing a second switch.

11. The method of claim 8, wherein transferring the receiving data to the feedback node comprises buffering the received data, and transferring the buffered data to the feedback node.

12. The method of claim 8, wherein generating the pulse signal comprises receiving a clock signal.

13. The method of claim 12, wherein generating the pulse signal further comprises delaying the received clock signal.

14. The method of claim 8, wherein transferring the generated complement data to the storage node of the latch circuit comprises deactivating an inverting amplifier responsive to the generated pulse signal, wherein an output of the inverting amplifier is coupled to the storage node of the latch circuit.

15. A system, comprising:
a processor; and
one or more memories;
wherein the processor includes one or more latch circuits;
wherein each latch circuit of the one or more latch circuits includes:
an first inverting amplifier, wherein an input of the first inverting amplifier is coupled to a storage node, and an output of the first inverting amplifier is coupled to a feedback node;
an input circuit configured to receive data and generate complement data and buffered data dependent upon the received data;
a first switch configured to selectively transfer the complement data to the storage node responsive to an assertion of a pulse signal; and
a second switch configured to selectively transfer the buffered data to the feedback node responsive to the assertion of the pulse signal.

16. The system of claim 15, wherein the input circuit includes one or more inverting amplifiers.

17. The system of claim 15, wherein each latch circuit of the one or more latch circuits further includes a pulse generator circuit configured to generate the pulse signal dependent upon a received clock signal.

18. The system of claim 17, wherein each pulse generator circuit includes a delay unit configured to delay the received clock signal.

19. The system of claim 15, wherein the first switch and the second switch each include a Complementary Metal-Oxide Semiconductor (CMOS) transmission gate.

20. The system of claim 15, wherein each latch circuit further includes an second inverting amplifier, wherein an input of the second inverting amplifier is coupled to the feedback node, and an output of the second inverting amplifier is coupled to the storage node.
